(19) United States
(12) Patent Application Publication
(10) Pub. No.: US 2025/0157825 A1
(43) Pub. Date: May 15, 2025

(54) ETCHING METHODS

(71) Applicant: Fujifilm Electronic Materials U.S.A., Inc., N. Kingstown, RI (US)

(72) Inventors: Keeyoung Park, Chandler, AZ (US); Mick Bjelopavlic, Chandler, AZ (US)

(21) Appl. No.: 18/940,961

(22) Filed: Nov. 8, 2024

Related U.S. Application Data
(60) Provisional application No. 63/548,256, filed on Nov. 13, 2023.

(51) Int. Cl. H01L 21/306

(52) U.S. Cl. CPC H01L 21/30604

(57) ABSTRACT

The present disclosure is directed to etching methods that are useful for, e.g., selectively removing silicon germanium (SiGe) from a semiconductor substrate as an intermediate step in a multistep semiconductor manufacturing process.

### CROSS-REFERENCE TO RELATED APPLICATION

The present application claims priority to U.S. Provisional Application Ser. No. 63/548,256, filed on Nov. 13, 2023, the contents of which are hereby incorporated by reference in their entirety.

### FIELD OF THE DISCLOSURE

The present disclosure relates to etching processes. In particular, the present disclosure relates to etching methods that can selectively etch silicon germanium in the presence of other exposed or underlying materials, such as metal conductors (e.g., copper), barrier materials, insulator materials (e.g., low-k dielectric materials).

### BACKGROUND OF THE DISCLOSURE

The semiconductor industry is rapidly decreasing the dimensions and increasing the density of electronic circuitry and electronic components in microelectronic devices, silicon chips, liquid crystal displays, MEMS (Micro Electro Mechanical Systems), printed wiring boards, and the like. The integrated circuits within them are being layered or stacked with constantly decreasing thicknesses of the insulating layer between each circuitry layer and smaller and smaller feature sizes. As the feature sizes have shrunk, patterns have become smaller, and device performance parameters tighter and more robust. As a result, various issues which heretofore could be tolerated, can no longer be tolerated or have become more of an issue due to the smaller feature size.

In the production of advanced integrated circuits, to minimize problems associated with the higher density and to optimize performance, both high k and low k insulators, and assorted barrier layer materials have been employed.

Silicon germanium (SiGe) can be utilized in the manufacturing of semiconductor devices, liquid crystal displays, MEMS (Micro Electro Mechanical Systems), printed wiring boards and the like, as nanowires and/or nanosheets. For example, it can be used as a gate material in a multigate device, such as a multiple-gate field-effect transistor (FET) (e.g., a gate-all-around FET).

### SUMMARY OF THE DISCLOSURE

In the construction of semiconductor devices, silicon germanium (SiGe) frequently needs to be etched. In the various types of uses and device environments of SiGe, other layers are in contact with or otherwise exposed at the same time as SiGe is etched. Highly selective etching of the SiGe in the presence of these other materials (e.g., metal conductors, dielectric, and hard marks) is typically needed for device yield and long life. The etching process for the SiGe may be a plasma etching process. However, using a plasma etching process on the SiGe layer may cause damage to either or both the gate insulating layer and the semiconductor substrate. In addition, the etching process may remove a portion of the semiconductor substrate by etching the gate insulating layer exposed by the gate electrode. The electrical characteristics of the transistor may be negatively impacted. To avoid such etching damage, additional protective device manufacturing steps may be employed, but at a significant cost.

The present disclosure relates to compositions and processes for selectively etching SiGe relative to hard mask layers, gate materials (e.g., SiN, poly-Si, or SiOx) and low-k dielectric layers (e.g., boron doped SiGe, SiN, SiOx, carbon doped oxide, or SiCO) that are present in the semiconductor device. More specifically, the present disclosure relates to compositions and processes for selectively etching SiGe relative to low-k dielectric layers, such as Si or SiOx.

In one aspect, the disclosure features a method for removing silicon germanium (SiGe), the method including: (1) contacting a semiconductor substrate containing a SiGe layer on a surface with a surface treatment composition to form a treated surface; and (2) contacting the treated surface with an etching composition to remove at least a portion of SiGe from the SiGe layer.

In another aspect, the disclosure features an article formed by the method described above, in which the article is a semiconductor device (e.g., an integrated circuit).

### DETAILED DESCRIPTION OF THE DISCLOSURE

As defined herein, unless otherwise noted, all percentages expressed should be understood to be percentages by weight to the total weight of the composition. In addition, the terms “layer” and “film” are used in this disclosure interchangeably.

In general, the disclosure features a method for removing silicon germanium (SiGe), the method including: (1) contacting a semiconductor substrate containing a SiGe layer on a surface with a surface treatment composition to form a treated surface; and (2) contacting the treated surface with an etching composition to remove at least a portion of SiGe from the SiGe layer. In some embodiments, steps (1) and (2) above can be repeated until the desired etching result is achieved. In some embodiments, the substrate can further include a silicon or silicon oxide layer on the surface of the semiconductor substrate. In some embodiments, the method does not substantially remove the silicon or silicon oxide layer.

Semiconductor substrates that can be treated by the surface treatment and etching compositions described herein typically are constructed of silicon, silicon germanium, silicon nitride, copper, Group III-V compounds such as GaAs, or any combination thereof. In some embodiments, the semiconductor substrate can be a silicon wafer, a copper wafer, a silicon dioxide wafer, a silicon nitride wafer, a silicon oxynitride wafer, a carbon doped silicon oxide wafer, a SiGe wafer, or a GaAs wafer. The semiconductor substrates may additionally contain exposed integrated circuit structures such as interconnect features (e.g., metal lines and dielectric materials). Metals and metal alloys used for interconnect features include, but are not limited to, aluminum, aluminum alloyed with copper, copper, titanium, tantalum, cobalt, nickel, silicon, polysilicon titanium nitride, tantalum nitride, tin, tungsten, SnAg, SnAg/Ni, CuNiSn, CuCoCu, and CoSn. The semiconductor substrate may also contain layers of interlayer dielectrics, silicon oxide, silicon nitride, titanium nitride, silicon carbide, silicon oxide carbide, silicon oxide nitride, titanium oxide, and carbon doped silicon oxides.

In some embodiments, the semiconductor substrate surface to be treated by the surface treatment and etching compositions described herein includes features containing silicon oxide (e.g., SiOx such as SiO₂), SiN, TiN, SiOC, SiON, Si, SiGe, Ge, or W. In some embodiments, the substrate semiconductor surface includes features containing SiGe, silicon oxide, and/or S.

In general, the semiconductor substrate surface to be treated by the surface treatment and etching compositions described herein includes patterns formed by a prior semiconductor manufacturing process (e.g., a lithographic process including applying a photoresist layer, exposing the photoresist layer to an actinic radiation, developing the photoresist layer, etching the semiconductor substrate beneath the photoresist layer, and/or removing the photoresist layer). In some embodiments, the patterns can include features having at least one (e.g., two or three) dimension (e.g., a length, a width, and/or a depth) of at most about 20 nm (e.g., at most about 15 nm, at most about 10 nm, or at most about 5 nm) and/or at least about 1 nm (e.g., at least about 2 nm or at least about 5 nm).

In some embodiments, the surface treatment composition described herein can include at least one (e.g., two, three, or four) Si-containing compound and optionally at least one (e.g., two, three, or four) aprotic solvent.

In general, the surface treatment composition described herein can include at least one Si-containing compound as a surface treatment agent. In some embodiments, the surface treatment agent can be a disilazane or a disiloxane. Examples of suitable disilazanes include hexamethyldisilazane, heptamethyldisilazane, N-methyl hexamethyldisilazane, 1,3-diphenyltetramethyldisilazane, or 1,1,3,3-tetraphenyl-1,3-dimethyldisilazane. Examples of suitable disiloxanes include 1,1,1-triethyl-3,3-dimethyldisiloxane, 1,1,3,3-tetra-n-octyldimethyldisiloxane, bis(nonafluorohexyl)tetramethyldisiloxane, 1,3-bis(trifluoropropyl)tetramethyldisiloxane, 1,3-di-n-butyltetramethyldisiloxane, 1,3-di-n-octyltetramethyldisiloxane, 1,3-diethyltetramethyldisiloxane, 1,3-diphenyltetramethyldisiloxane, hexa-n-butyldisiloxane, hexaethyldisiloxane, hexavinyldisiloxane, 1,1,1,3,3-pentamethyl-3-acetoxydisiloxane, 1-allyl-1,1,3,3-tetramethyldisiloxane, 1,3-bis(3-aminopropyl)tetramethyldisiloxane, 1,3-bis(heptadecafluoro-1,1,2,2-tetrahydrodecyl)tetramethyldisiloxane, 1,3-divinyltetraphenyldisiloxane, 1,3-divinyltetramethyldisiloxane, 1,3-diallyltetrakis(trimethylsiloxy)disiloxane, 1,3-diallyltetramethyldisiloxane, 1,3-diphenyltetrakis(dimethylsiloxy)disiloxane, (3-chloropropyl)pentamethyldisiloxane, 1,3-divinyltetrakis(trimethylsiloxy)disiloxane, 1,1,3,3-tetraisopropyldisiloxane, 1,1,3,3-tetravinyldimethyldisiloxane, 1,1,3,3-tetracyclopentyldichlorodisiloxane, vinylpentamethyldisiloxane, 1,3-bis(3-chloroisobutyl)tetramethyldisiloxane, hexaphenyldisiloxane, 1,3-bis[(bicyclo[2.2.1]hept-2-enyl)ethyl]tetramethyldisiloxane, 1,1,1-triethyl-3,3,3-trimethyldisiloxane, 1,3-bis(3-methacryloxypropyl)tetramethyl-disiloxane, 1,3-bis(chloromethyl)tetramethyldisiloxane, 1,1,3,3-tetramethyl-1,3-diethoxydisiloxane, 1,1,3,3-tetraphenyldimethyldisiloxane, methacryloxypentamethyl-disiloxane, pentamethyldisiloxane, 1,3-bis(3-chloropropyl)tetramethyldisiloxane, 1,3-bis(4-hydroxybutyl)tetramethyldisiloxane, 1,3-bis(triethoxysilylethyl)tetramethyl-disiloxane, 3-aminopropylpentamethyldisiloxane, 1,3-bis(2-aminoethylaminomethyl)-tetramethyldisiloxane, 1,3-bis(3-carboxypropyl)tetramethyldisiloxane, 1,3-dichloro-1,3-diphenyl-1,3-dimethyldisiloxane, 1,3-diethynyltetramethyldisiloxane, n-butyl-1,1,3,3-tetramethyldisiloxane, 1,3-dichlorotetraphenyldisiloxane, 1,3-dichlorotetramethyl-disiloxane, 1,3-di-t-butyldisiloxane, 1,3-dimethyltetramethoxydisiloxane, 1,3-divinyl-tetraethoxydisiloxane, 1,1,3,3-tetraethoxy-1,3-dimethyldisiloxane, vinyl-1,1,3,3-tetramethyldisiloxane, platinum-[1,3-bis(cyclohexyl)imidazol-2-ylidene hexachloro-disiloxane, 1,1,3,3-tetraisopropyl-1-chlorodisiloxane, 1,1,1-trimethyl-3,3,3-triphenyldisiloxane, or 1,3-bis(trimethylsiloxy)-1,3-dimethyldisiloxane.

In some embodiments, the at least one Si-containing compound is from at least about 0.5 wt % (e.g., at least about 1 wt %, at least about 2 wt %, at least about 3 wt %, at least about 4 wt %, at least about 5 wt %, at least about 6 wt %, at least about 7 wt %, or at least about 8 wt %) to at most about 100 wt % (e.g., at most about 90 wt %, at most about 80 wt %, at most about 70 wt %, at most about 60 wt %, at most about 50 wt %, at most about 40 wt %, at most about 30 wt %, at most about 20 wt %, at most about 10 wt %, at most about 9.5 wt %, at most about 9 wt %, at most about 8 wt %, or at most about 7 wt %) of the surface treatment compositions described herein.

As used herein, the phrase “aprotic solvent” refers to a solvent that lacks a hydrogen atom bounded to an oxygen (e.g., as in a hydroxyl group) or a nitrogen (e.g., as in an amine group). In some embodiments, the aprotic solvent can be a polar aprotic solvent having a relatively high dipole moment (e.g., at least 2.7). In some embodiments, the aprotic solvent is selected from the group consisting of carbonate solvents (e.g., propylene carbonate or dimethyl carbonate), lactones (e.g., gamma-butyrolactone), ketones (e.g., cyclohexanone), aromatic hydrocarbons (e.g., toluene, xylene, or mesitylene), siloxanes (e.g., hexamethyldisiloxane), glycol dialkyl ethers (e.g., dipropylene glycol dimethyl ether or propylene glycol dimethyl ether), glycol alkyl ether acetates (e.g., propylene glycol methyl ether acetate (PGMEA)), esters (e.g., ethyl lactate), ureas (e.g., 1,3-dimethyl-2-imidizolidinone or 1,3-dimethyl-3,4,5,6-tetrahydro-2(1H)-pyrimidinone), lactams, dimethyl sulfoxide, and N-methyl pyrrolidone. In some embodiments, the aprotic solvent is a carbonate solvent (e.g., propylene carbonate). In some embodiments, the surface treatment composition can be substantially free of an aprotic solvent.

In some embodiments, the at least one aprotic solvent is from at least about 0 wt % (e.g., at least about 1 wt %, at least about 5 wt %, at least about 10 wt %, at least about 20 wt %, at least about 30 wt %, at least about 40 wt %, at least about 50 wt %, at least about 60 wt %, at least about 70 wt %, at least about 80 wt %, at least about 90 wt %, at least about 91 wt %, at least about 92 wt %, at least about 93 wt %, at least about 94 wt %, at least about 95 wt %, at least about 96 wt %, at least about 97 wt %, or at least about 98 wt %) to at most about 99.9 wt % (e.g., at most about 99.5 wt %, at most about 99 wt %, at most about 98 wt %, or at most about 97 wt %) of the surface treatment composition described herein.

Without wishing to be bound by theory, it is believed that treating a semiconductor substrate with a surface treatment composition described herein before applying an etching composition to remove SiGe can passivate the substrate surface, which can improve the SiGe etch selectivity while avoiding an oxidation step that was conventionally used to form a protective layer before etching.

In some embodiments, the etching composition described herein (e.g., an etching composition for selectively removing SiGe) includes (1) at least one fluorine-containing acid, the at least one fluorine-containing acid containing hydrofluoric acid or hexafluorosilicic acid; (2) at least one oxidizing agent; (3) at least one catalyst containing sulfuric acid, a sulfonic acid, or a phosphonic acid; (4) at least one organic acid or an anhydride thereof, the at least one organic acid containing formic acid, acetic acid, propionic acid, or butyric acid; (5) at least one polymerized naphthalene sulfonic acid or a salt thereof; and (6) at least one amine, the at least one amine containing an amine of formula (1): N—R₁R₂R₃, wherein R₁ is C₁-C₈ alkyl optionally substituted by OH or NH₂, R₂ is H or C₁-C₈ alkyl optionally substituted by OH, and R₃ is C₁-C₈ alkyl optionally substituted by OH.

In some embodiments, the etching composition described herein can include at least one (e.g., two, three, or four) fluorine-containing acid. The fluorine-containing acid described herein can be an inorganic acid, such as HF or H₂SiF₆. In some embodiments, the at least one fluorine-containing acid is in an amount of at least about 0.01 wt % (e.g., at least about 0.02 wt %, at least about 0.04 wt %, at least about 0.05 wt %, at least about 0.06 wt %, at least about 0.08 wt %, at least about 0.1 wt %, at least about 0.2 wt %, at least about 0.4 wt %, at least about 0.5 wt %, at least about 0.6 wt %, at least about 0.8 wt %, at least about 1 wt %, at least about 1.2 wt %, at least about 1.4 wt %, or at least about 1.5 wt %) to at most about 2 wt % (e.g., at most about 1.9 wt %, at most about 1.8 wt %, at most about 1.7 wt %, at most about 1.6 wt %, at most about 1.5 wt %, at most about 1.2 wt %, at most about 1 wt %, or at most about 0.5 wt %) of the etching composition described herein. Without wishing to be bound by theory, it is believed that fluorine-containing acid can facilitate and enhance the removal of SiGe on a semiconductor substrate during the etching process. On the other hand, the fluorine-containing acid also increases the removal of certain dielectric materials (e.g., SiOx and boron doped SiGe) and therefore its amount in the etch compositions described herein preferably should be limited if it is desirable to minimize the removal of such dielectric materials.

In some embodiments, the etching composition described herein can include at least one (e.g., two, three, or four) oxidizing agent suitable for use in microelectronic applications. Examples of suitable oxidizing agents include oxidizing acids (e.g., nitric acid, permanganic acid, or potassium permanganate) and salts thereof, peroxides (e.g., hydrogen peroxide, dialkylperoxides, or urea hydrogen peroxide), persulfonic acid (e.g., hexafluoropropanepersulfonic acid, methanepersulfonic acid, trifluoromethane-persulfonic acid, or p-toluenepersulfonic acid) and salts thereof, ozone, peroxycarboxylic acids (e.g., peracetic acid) and salts thereof, perphosphoric acid and salts thereof, persulfuric acid and salts thereof (e.g., ammonium persulfate or tetramethylammonium persulfate), perchloric acid and salts thereof (e.g., ammonium perchlorate, sodium perchlorate, or tetramethylammonium perchlorate), and periodic acid and salts thereof (e.g., periodic acid, ammonium periodate, or tetramethylammonium periodate). These oxidizing agents can be used singly or in combination.

In some embodiments, the at least one oxidizing agent can be from at least about 5 wt % (e.g., at least about 6 wt %, at least about 7 wt %, at least about 8 wt %, at least about 9 wt %, at least about 10 wt %, at least about 11 wt %, at least about 13 wt %, or at least about 15 wt %) to at most about 20 wt % (e.g., at most about 18 wt %, at most about 16 wt %, at most about 15 wt %, at most about 14 wt %, at most about 12 wt %, or at most about 10 wt %) of the etching composition described herein. Without wishing to be bound by theory, it is believed that the oxidizing agent can facilitate and enhance the removal of SiGe on a semiconductor substrate.

In some embodiments, the etching composition described herein can optionally include at least one (e.g., two, three, or four) catalyst. In general, the catalyst can be an acid different from the fluorine-containing acid. For example, the catalyst can be an organic acid or an acid that does not contain fluorine. Examples of suitable catalysts include sulfuric acid (H₂SO₄), sulfonic acids, and phosphonic acids.

Examples of suitable sulfonic acids include alkylsulfonic acids (including substituted or unsubstituted alkylsulfonic acid) and arylsulfonic acids (including substituted or unsubstituted arylsulfonic acid). Examples of suitable alkylsulfonic acids include methanesulfonic acid, trifluoromethanesulfonic acid (or triflic acid), and 2-hydroxyethanesulfonic acid (or isethionic acid). Examples of suitable arylsulfonic acids include p-toluenesulfonic acid and naphthalene sulfonic acid.

Examples of suitable phosphonic acids include those of formula (II):

R—PO(OH)₂ (II),

in which R is H, C₁-C₁₀ alkyl, or aryl. Examples of suitable phosphonic acids include unsubstituted phosphonic acid (H₃PO₃) and phenylphosphonic acid.

Without wishing to be bound by theory, it is believed that including a catalyst into the etching composition described herein can increase the rate of formation of a peracid (such as peracetic acid), which together with the fluorine-containing acid, can enhance SiGe removal. It is also believed that the catalyst can significantly inhibit the removal of certain dielectric materials (e.g., SiOx) in the semiconductor substrate during the etching process.

In some embodiments, the at least one catalyst is in an amount of at least about 0.1 wt % (e.g., at least about 0.2 wt %, at least about 0.4 wt %, at least about 0.5 wt %, at least about 0.6 wt %, at least about 0.8 wt %, at least about 1 wt %, at least about 1.2 wt %, at least about 1.4 wt %, or at least about 1.5 wt %) to at most about 5 wt % (e.g., at most about 4.5 wt %, at most about 4 wt %, at most about 3.5 wt %, at most about 3 wt %, at most about 2.5 wt %, at most about 2 wt %, at most about 1.5 wt %, or at most about 1 wt %) of the etching composition of this disclosure. In some embodiments, the at least one catalyst can be omitted from the etching composition of this disclosure (e.g., when the etching composition includes a glycol).

In some embodiments, the etching composition described herein can include at least one (e.g., two, three, or four) organic acid or an anhydride thereof. In general, such an organic acid is different from the fluorine-containing acid and the catalyst described above. In some embodiments, the organic acid can be formic acid, acetic acid, propionic acid, or butyric acid. In some embodiments, the organic acid anhydride can be formic anhydride, acetic anhydride, propionic anhydride, or butyric anhydride. In some embodiments, the etching composition can include both an organic acid and an anhydride (e.g., the anhydride of the organic acid). Without wishing to be bound by theory, it is believed that the organic acid or an anhydride thereof can facilitate and enhance the removal of SiGe on a semiconductor substrate.

In some embodiments, the total amount of the at least one organic acid or an anhydride thereof can be from at least about 30 wt % (e.g., at least about 35 wt %, at least about 40 wt %, at least about 45 wt %, at least about 50 wt %, at least about 55 wt %, or at least about 60 wt %) to at most about 90 wt % (e.g., at most about 85 wt %, at most about 80 wt %, at most about 75 wt %, at most about 70 wt %, at most about 65 wt %, at most about 60 wt %, at most about 55 wt %, at most about 50 wt %, at most about 45 wt %, or at most about 40 wt %) of the etching composition described herein.

In some embodiments, the etching composition described herein can include at least one polymerized naphthalene sulfonic acid (or poly(naphthalene sulfonic acid)) or a salt thereof, e.g., as a surfactant or selective inhibitor. In some embodiments, the polymerized naphthalene sulfonic acid can be a sulfonic acid having the following chemical structure:

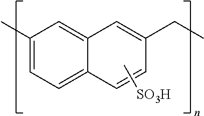

in which n is 3, 4, 5, or 6. Commercially available examples of such polymerized naphthalene sulfonic acids include Takesurf A-47 series products available from Takemoto Oil & Fat Co., Ltd. Without wishing to be bound by theory, it is believed that the polymerized naphthalene sulfonic acid or a salt thereof can selectively inhibit the removal of SiN, poly-Si, and SiCO when SiGe is removed from a semiconductor substrate using the etching composition of this disclosure.

In some embodiments, the at least one polymerized naphthalene sulfonic acid or a salt thereof (or the total amount of a polymerized naphthalene sulfonic acid and a salt thereof if both are present) can be from at least about 0.001 wt % (e.g., at least about 0.005 wt %, at least about 0.01 wt %, at least about 0.02 wt %, at least about 0.03 wt %, at least about 0.04 wt %, at least about 0.05 wt %, or at least about 0.1 wt %) to at most about 0.15 wt % (e.g., at most about 0.14 wt %, at most about 0.12 wt %, at most about 0.1 wt %, at most about 0.08 wt %, at most about 0.06 wt %, at most about 0.05 wt %, or at most about 0.02 wt %) of the etching composition described herein.

In some embodiments, the etching composition described herein can optionally include at least one (e.g., two, three, or four) pyridine containing compound. For example, the pyridine containing compound can include pyridine optionally substituted by C₁-C₆ alkyl (e.g., methyl or ethyl), a pyridine containing acid, a pyridine containing alcohol, or a salt thereof (e.g., a HCl salt thereof). Examples of suitable pyridine containing compound include picolinic acid, dipicolinic acid, nicotinic acid, isonicotinic acid, 2-amino-isonicotinic acid, isonicotinic acid N-oxide, 4-pyridylacetic acid, 3-pyridylacetic acid, 2-pyridylacetic acid, 4-pyridinepropanol, 3-pyridinepropanol, 2-methylpyridien, 3-methylpyridine, and a salt thereof (e.g., a HCl salt of an acid). Without wishing to be bound by theory, it is believed that the pyridine containing compound can selectively inhibit the removal of boron doped SiGe (which is needed for improved carrier mobility) when SiGe is removed from a semiconductor substrate using the etching composition of this disclosure.

In some embodiments, the at least one pyridine containing compound is in an amount of at least about 0.01 wt % (e.g., at least about 0.02 wt %, at least about 0.04 wt %, at least about 0.05 wt %, at least about 0.06 wt %, at least about 0.08 wt %, at least about 0.1 wt %, at least about 0.2 wt %, at least about 0.3 wt %, at least about 0.4 wt %, or at least about 0.5 wt %) to at most about 1 wt % (e.g., at most about 0.9 wt %, at most about 0.8 wt %, at most about 0.7 wt %, at most about 0.6 wt %, at most about 0.5 wt %, at most about 0.4 wt %, at most about 0.2 wt %, or at most about 0.1 wt %) of the etching composition of this disclosure.

In some embodiments, the etching composition described herein can include at least one (e.g., two, three, or four) amine. In some embodiments, the amine can be an amine of formula (1): N—R₁R₂R₃, wherein R₁ is C₁-C₈ alkyl optionally substituted by OH or NH₂, R₂ is H or C₁-C₈ alkyl optionally substituted by OH, and R₃ is C₁-C₈ alkyl optionally substituted by OH. Examples of suitable amines of formula (I) include diisopropylamine, N-butyldiethanolamine, N-(3-aminopropyl)-diethanolamine, N-octylglucamine, N-ethylglucamine, N-methylglucamine, and 1-[bis(2-hydroxyethyl)amino]-2-propanol. Without wishing to be bound by theory, it is believed that the amine can selectively inhibit the removal of SiN, poly-Si, and SiCO when SiGe is removed from a semiconductor substrate using the etching composition described herein.

In some embodiments, the at least one amine can be from at least about 0.001 wt % (e.g., at least about 0.002 wt %, at least about 0.005 wt %, at least about 0.008 wt %, at least about 0.01 wt %, at least about 0.02 wt %, at least about 0.05 wt %, or at least about 0.1 wt %) to at most about 0.15 wt % (e.g., at most about 0.14 wt %, at most about 0.12 wt %, at most about 0.1 wt %, at most about 0.08 wt %, at most about 0.06 wt %, or at most about 0.05 wt %) of the etching composition described herein.

In some embodiments, the etching composition described herein can include water as a solvent. In some embodiments, the water can be de-ionized and ultra-pure, contain no organic contaminants and have a minimum resistivity of about 4 to about 17 mega Ohms, or at least about 17 mega Ohms. In some embodiments, the water is in an amount of from at least about 10 wt % (e.g., at least about 15 wt %, at least about 20 wt %, at least about 25 wt %, at least about 30 wt %, at least about 35 wt %, or at least about 40 wt %) to at most about 50 wt % (e.g., at most about 45 wt %, at most about 40 wt %, at most about 35 wt %, at most about 30 wt %, at most about 25 wt %, at most about 20 wt %, or at most about 15 wt %) of the etching composition. Without wishing to be bound by theory, it is believed that, if the amount of water is greater than 50 wt % of the composition, it would result in high etch rate of Si and SiOx, whose removal should be minimized during the etching process. On the other hand, without wishing to be bound by theory, it is believed that the etching composition of this disclosure should include a certain level of water (e.g., at least about 10 wt %) to keep all other components solubilized and to avoid reduction in the etching performance. In addition. without wishing to be bound by theory, it is believed that reducing the amount of water within the above ranges can significantly inhibit the removal of certain dielectric materials (e.g., boron doped SiGe) in the semiconductor substrate during the etching process.

In some embodiments, the etching composition described herein can optionally further include at least one (e.g., two, three, or four) organic solvent. In some embodiments, the at least one organic solvent can include an ester, an alcohol, or an alkylene glycol ether. Examples of suitable organic solvents include propyl acetate, propylene glycol, hexylene glycol, 1,3-propanediol, ethylene glycol monobutyl ether (EGBE), and 3-methoxy-3-methyl-1-butanol. In some embodiments, the at least one organic solvent can be from at least about 10 wt % (e.g., at least about 15 wt %, at least about 20 wt %, at least about 25 wt %, at least about 30 wt %, or at least about 35 wt %) to at most about 40 wt % (e.g., at most about 35 wt %, at most about 30 wt %, at most about 25 wt %, at most about 20 wt %, or at most about 15 wt %) of the etching composition.

In some embodiments, the etching composition described herein can optionally further include at least one (e.g., two, three, or four) boronic acid. For example, the boronic acid can be of the following formula: R—B(OH)₂, in which R is C₁-C₁₀ alkyl, aryl, or heteroaryl where aryl or heteroaryl can be optionally substituted by one to six (e.g., 1, 2, 3, 4, 5, or 6) C₁-C₁₀ alkyl. Examples of suitable boronic acids include phenyl boronic acid and naphthalene-1-boronic acid.

In some embodiments, the at least one boronic acid can be from at least about 0.01 wt % (e.g., at least about 0.02 wt %, at least about 0.05 wt %, at least about 0.1 wt %, at least about 0.2 wt %, or at least about 0.3 wt %) to at most about 0.5 wt % (e.g., at most about 0.4 wt %, at most about 0.3 wt %, at most about 0.2 wt %, at most about 0.1 wt %, at most about 0.08 wt %, or at most about 0.05 wt %) of the etching composition. Without wishing to be bound by theory, it is believed that including a boronic acid in the etching composition of this disclosure can inhibit the SiOx etch rate.

In some embodiments, the etching composition described herein can optionally further include at least one (e.g., two, three, or four) polyamine (e.g., polyethylenimine). In some embodiments, the at least one polyamine can be from at least about 0.001 wt % (e.g., at least about 0.002 wt %, at least about 0.005 wt %, at least about 0.01 wt %, at least about 0.02 wt %, at least about 0.04 wt %, or at least about 0.05 wt %) to at most about 0.5 wt % (e.g., at most about 0.4 wt %, at most about 0.3 wt %, at most about 0.2 wt %, at most about 0.1 wt %, at most about 0.08 wt %, at most about 0.06 wt %, or at most about 0.05 wt %) of the etching composition. Without wishing to be bound by theory, it is believed that including a polyamine in the etching composition described herein can inhibit the etch rate of SiGe doped with boron.

In some embodiments, the etching composition described herein can optionally further include at least one (e.g., two, three, or four) silane (e.g., 3-aminopropyl triethoxysilane). In some embodiments, the at least one silane includes a silane of formula (III):

Si—R₄R₅R₆R₇ (III),

in which each of R₄, R₅, R₆, and R₇, independently, is N(RR′), RC(O)O, C₁-C₈ alkoxy (e.g., methoxy or ethoxy), C₁-C₁₀ alkyl (e.g., methyl, butyl, hexyl, octyl, dodecyl, or octadecyl) optionally substituted by N(RR′) or Si(RₐR_{b}R_{c}). Each of R and R′, independently, is C₁-C₁₀ alkyl and each of Rₐ, R_{b}, and R_{c}, independently, is C₁-C₁₀ alkyl or C₁-C₁₀ alkoxy. Examples of suitable silanes include 3-aminopropyl triethoxysilane, methyltrimethoxysilane, dimethylaminotrimethylsilane, acetoxytrimethylsilane, octyltrimethoxysilane, butyltrimethoxysilane, dodecyltrimethoxysilane, hexyltrimethoxysilane, octadecyltrimethoxysilane, or bis(trimethoxysilyl)methane.

In some embodiments, the at least one silane can be from at least about 0.001 wt % (e.g., at least about 0.002 wt %, at least about 0.005 wt %, at least about 0.01 wt %, at least about 0.02 wt %, at least about 0.04 wt %, or at least about 0.05 wt %) to at most about 0.5 wt % (e.g., at most about 0.4 wt %, at most about 0.3 wt %, at most about 0.2 wt %, at most about 0.1 wt %, at most about 0.08 wt %, at most about 0.06 wt %, or at most about 0.05 wt %) of the etching composition described herein. Without wishing to be bound by theory, it is believed that including a silane in the etching composition described herein can inhibit the etch rate of SiGe doped with boron.

In some embodiments, the etching composition described herein can have a pH of at least about 0 (e.g., at least about 0.2, at least about 0.4, at least about 0.5, at least about 0.6, at least about 0.8, at least about 1, at least about 1.2, at least about 1.4, at least about 1.5, at least about 1.6, at least about 1.8, at least about 2, at least about 2.2, at least about 2.4, or at least about 2.5) and/or at most about 3 (e.g., at most about 2.8, at most about 2.6, at most about 2.5, at most about 2.4, at most about 2.2, at most about 2, or at most about 1.5). Without wishing to be bound by theory, it is believed that an etching composition having a pH higher than 3 would not have sufficient SiGe selectivity relative to low-k dielectric materials (e.g., SiOx) as such an etching composition may have a significantly increased low-k dielectric material etch rate. Further, it is believed that an etching composition having a pH lower than 0 could decompose certain components in the composition due to strong acidity.

In addition, in some embodiments, the etching composition described herein can contain additives such as, pH adjusting agents, corrosion inhibitors, surfactants, additional organic solvents, biocides, and defoaming agents as optional components. Examples of suitable additives include alcohols (e.g., polyvinyl alcohol), organic acids (e.g., iminodiacetic acid, malonic acid, oxalic acid, succinic acid, and malic acid), and inorganic acids (e.g., boric acid). Examples of suitable defoaming agents include polysiloxane defoamers (e.g., polydimethylsiloxane), polyethylene glycol methyl ether polymers, ethylene oxide/propylene oxide copolymers, and glycidyl ether capped acetylenic diol ethoxylates (such as those described in U.S. Pat. No. 6,717,019, herein incorporated by reference). Examples of suitable surfactants may be cationic, anionic, nonionic or amphoteric.

In general, the etching composition of the present disclosure can have a relatively high SiGe/dielectric material (e.g., boron doped SiGe (SiGe:B), SiN, SiOx, polysilicon, or SiCO) etch selectivity (i.e., a high ratio of SiGe etch rate over dielectric material etch rate). In some embodiments, the etching composition can have a SiGe/dielectric material (e.g., SiGe/SiOx or SiGe/Si) etch selectivity of at least about 2 (e.g., at least about 3, at least about 4, at least about 5, at least about 6, at least about 7, at least about 8, at least about 9, at least about 10, at least about 15, at least about 20, at least about 30, at least about 40, or at least about 50) and/or at most about 500 (e.g., at most about 100).

In some embodiments, the surface treatment composition and/or etching composition described herein can be substantially free of one or more of additive components, in any combination, if more than one. Such components are selected from the group consisting of organic solvents, polymers (e.g., non-ionic, cationic, or anionic polymers), oxygen scavengers, quaternary ammonium compounds (e.g., salts or hydroxides), alkaline bases (such as NaOH, KOH, LiOH, Mg(OH)₂, and Ca(OH)₂), surfactants (e.g., cationic, anionic, or non-ionic surfactants), defoamers, fluorine-containing compounds (e.g., fluoride compounds, fluorinated compounds (such as fluorinated polymers/surfactants), or fluorine-containing compounds that are not an acid), silicon-containing compounds such as silanes (e.g., alkoxysilanes), nitrogen-containing compounds (e.g., amino acids, amines, imines (e.g., amidines such as 1,8-diazabicyclo[5.4.0]-7-undecene (DBU) and 1,5-diazabicyclo[4.3.0]non-5-ene (DBN)), amides, or imides), abrasives (e.g., fumed silica, ceria abrasives, non-ionic abrasives, surface modified abrasives, negatively/positively charged abrasive, or ceramic abrasive composites), plasticizers, oxidizing agents (e.g., peroxides such as hydrogen peroxide, and periodic acid), corrosion inhibitors (e.g., azole or non-azole corrosion inhibitors), electrolytes (e.g., polyelectrolytes), silicates, cyclic compounds (e.g., azoles (such as diazoles, triazoles, or tetrazoles), triazines, and cyclic compounds containing at least two rings such as substituted or unsubstituted naphthalenes, or substituted or unsubstituted biphenylethers), chelating agents, buffering agents, acids such as organic acids (e.g., carboxylic acids such as hydroxycarboxylic acids, polycarboxylic acids, and sulfonic acid) and inorganic acids (e.g., sulfuric acid, sulfurous acid, nitrous acid, nitric acid, phosphorous acid, and phosphoric acid), salts (e.g., halide salts or metal salts), and catalysts (e.g., metal-containing catalysts). As used herein, a component that is “substantially free” from a composition refers to an ingredient that is not intentionally added into the composition. In some embodiments, the surface treatment composition and/or etching composition described herein can have at most about 1000 ppm (e.g., at most about 500 ppm, at most about 250 ppm, at most about 100 ppm, at most about 50 ppm, at most about 10 ppm, or at most about 1 ppm) of one or more of the above components that are substantially free from the composition. In some embodiments, the surface treatment composition and/or etching compositions described herein can be completely free of one or more of the above components.

The surface treatment composition and/or etching composition described herein can be prepared by simply mixing the components together, or can be prepared by blending two compositions contained in a kit. For example, to prepare an etching composition described herein, the first composition in the kit can be an aqueous solution of an oxidizing agent (e.g., H₂O₂). The second composition in the kit can contain the remaining components of the etching composition at predetermined ratios in a concentrated form such that the blending of the two compositions will yield a desired etching composition.

In some embodiments, the etching method described herein can include the steps of:
(A) providing a semiconductor substrate containing a SiGe layer on a surface;
(B) optionally, contacting the semiconductor substrate with a cleaning composition;
(C) contacting the semiconductor substrate with a surface treatment composition to form a treated surface;
(D) contacting the treated surface with an etching composition to remove at least a portion of SiGe from the SiGe layer (e.g., substantially the entire SiGe layer);
(E) optionally, rinsing the semiconductor substrate with one or more suitable rinse solvents; and
(F) optionally, drying the semiconductor substrate (e.g., by any suitable means that removes the rinse solvent and does not compromise the integrity of the semiconductor substrate).

In some embodiments, steps (C) and (D) above can be repeated one or more (e.g., two or three) times during the etching method described herein to achieve a desired etching result.

In some embodiments, the method does not substantially remove a dielectric material (e.g., SiOx, SiN, polysilicon, SiCO, or SiGe doped with boron) in the semiconductor substrate. For example, the method does not remove more than about 5% by weight (e.g., more than about 3% by weight or more than about 1% by weight) of a dielectric material in the semiconductor substrate.

In some embodiments, the SiGe layer in a semiconductor substrate can include at least about 10 at % (e.g., at least about 12 at %, at least about 14 at %, at least about 15 at %, at least about 16 at %, at least about 18 at %, or at least about 20 at %) Ge and/or at most about 65 at % (e.g., at most about 60 at %, at most about 55 at %, at most about 50 at %, at most about 45 at %, at most about 40 at %, at most about 35 at %, at most about 34 at %, at most about 32 at %, at most about 30 at %, at most about 28 at %, at most about 26 at %, at most about 25 at %, at most about 24 at %, at most about 22 at %, at most about 20 at %, at most about 18 at %, at most about 16 at %, or at most about 15 at %) Ge in the SiGe layer. As used herein, “at %” refers to atomic percentage, which is equivalent to molar percentage. Without wishing to be bound by theory, it is believed that a SiGe layer containing from about 10 at % to about 35 at % Ge can be more easily removed from a semiconductor substrate by an etching composition compared to a layer containing more than 35 at % or less than 10 at % Ge.

The semiconductor substrates containing SiGe to be etched in this method can contain organic and organometallic residues, and a range of metal oxides, some or all of which may also be removed during the etching process.

A semiconductor substrate can be contacted with the optional cleaning composition, the surface treatment composition, or the etching composition by any suitable method, such as placing the composition into a tank and immersing and/or submerging the semiconductor substrate into the composition, spraying the composition onto the semiconductor substrate, streaming the composition onto the semiconductor substrate, or any combinations thereof.

In some embodiments, the cleaning composition described herein can be an aqueous HF solution and can be used to remove an oxide layer (e.g., a native oxide layer) formed on a semiconductor substrate (e.g., on a SiGe layer on the semiconductor substrate). In some embodiments, a native oxide layer can be formed when the semiconductor is exposed to air. Without wishing to be bound by theory, it is believed that a native oxide layer on a SiGe layer can lower the SiGe etch rate during the etching process and therefore is preferably removed before the etching process.

The etching composition of the present disclosure can be effectively used up to a temperature of about 85° C. (e.g., from about 20° C. to about 80° C., from about 25° C. to about 65° C., or from about 55° C. to about 65° C.). The etch rates of SiGe increase with temperature in this range, thus the processes at a higher temperature can be run for shorter times. Conversely, lower etching temperatures typically require longer etching times.

Etching times can vary over a wide range depending on the particular etching method, thickness, and temperature employed. When etching in an immersion batch type process, a suitable time range is, for example, up to about 10 minutes (e.g., from about 1 minute to about 7 minutes, from about 1 minute to about 5 minutes, or from about 2 minutes to about 4 minutes). Etching times for a single wafer process can range from about 30 seconds to about 5 minutes (e.g., from about 30 seconds to about 4 minutes, from about 1 minute to about 3 minutes, or from about 1 minute to about 2 minutes).

To further promote the etching ability of the etching composition of the present disclosure, mechanical agitation means can be employed. Examples of suitable agitation means include circulation of the etching composition over the substrate, streaming or spraying the etching composition over the substrate, and ultrasonic or megasonic agitation during the etching process. The orientation of the semiconductor substrate relative to the ground can be at any angle. Horizontal or vertical orientations are preferred.

Subsequent to the etching, the semiconductor substrate can be rinsed with a suitable rinse solvent for about 5 seconds up to about 5 minutes with or without agitation means. Multiple rinse steps employing different rinse solvents can be employed. Examples of suitable rinse solvents include, but are not limited to, deionized (DI) water, methanol, ethanol, isopropyl alcohol, N-methylpyrrolidinone, gamma-butyrolactone, dimethyl sulfoxide, ethyl lactate and propylene glycol monomethyl ether acetate. Alternatively, or in addition, aqueous rinses with pH>8 (such as dilute aqueous ammonium hydroxide) can be employed. Examples of rinse solvents include, but are not limited to, dilute aqueous ammonium hydroxide, DI water, methanol, ethanol, and isopropyl alcohol. The rinse solvent can be applied using means similar to that used in applying an etching composition described herein. The etching composition may have been removed from the semiconductor substrate prior to the start of the rinsing step or it may still be in contact with the semiconductor substrate at the start of the rinsing step. In some embodiments, the temperature employed in the rinsing step is between 16° C. and 27° C.

Optionally, the semiconductor substrate is dried after the rinsing step. Any suitable drying means known in the art can be employed. Examples of suitable drying means include spin drying, flowing a dry gas across the semiconductor substrate, or heating the semiconductor substrate with a heating means such as a hotplate or infrared lamp, Maragoni drying, rotagoni drying, IPA drying or any combinations thereof. Drying times will be dependent on the specific method employed but are typically on the order of 30 seconds up to several minutes.

In some embodiments, the etching method described herein further includes forming a semiconductor device (e.g., an integrated circuit device such as a semiconductor chip) from the semiconductor substrate obtained by the method described above.

The present disclosure is illustrated in more detail with reference to the following examples, which are for illustrative purposes and should not be construed as limiting the scope of the present disclosure.

### EXAMPLES

Any percentages listed are by weight (wt %) unless otherwise specified. Controlled stirring during testing was done with a ½ inch stirring bar at 250 rpm unless otherwise noted.

### General Procedure 1

### Formulation Blending

Samples of surface treatment and etching compositions were prepared by adding, while stirring, to the calculated amount of the solvent the remaining components of the formulation. After a uniform solution was achieved, optional additives, if used, were added.

### General Procedure 2

### Materials and Methods

Blanket film etch rate measurements on films were carried out using commercially available unpatterned 300 mm diameter wafers that were diced into 0.5″×1.0″ test coupons for evaluation. Primary blanket film materials used for testing included 1) a SiGe film of about 500 Å thickness and containing 25 at % Ge deposited on a silicon substrate (SiGe25-1); 2) a SiGe film of about 180 Å thickness and containing 25 at % Ge deposited on a silicon substrate (SiGe25-2); 3) a SiGe film of about 185 Å thickness and containing 28 at % Ge deposited on a silicon substrate (SiGe28); 4) a SiGe film of about 180 Å thickness and containing 31.5 at % Ge deposited on a silicon substrate (SiGe31.5); 5) a SiO₂ film of about 1200 Å thickness deposited on a silicon substrate, and 6) a poly-Si film of about 180 Å thickness deposited on a SiGe substrate.

The thickness of each blanket film test coupon was measured pre-treatment and post-treatment of an etching composition to determine blanket film etch rates. The film thicknesses were measured pre-treatment and post-treatment by Ellipsometry using a Woollam Variable Angle Spectroscopic Ellipsometer (VASE).

### General Procedure 3

Etching Evaluation with Beaker Test

All blanket film etch testing was carried out at room temperature (25° C.) in a 125 mL PFA bottle containing 100 g of a sample solution with continuous stirring at 250 rpm, with cap in place at all times to minimize evaporative losses. All blanket test coupons having a blanket dielectric film exposed on one side to the sample solution were diced by diamond scribe into 0.5″×1.0″ square test coupon size for beaker scale testing. Each individual test coupon was held into position using a single 4″ long, locking plastic tweezers clip. The test coupon, held on one edge by the locking tweezers clip, was suspended into the 125 mL PFA bottle and immersed into the 100 g surface treatment solution (if used) and/or 100 g etching solution while the solution was stirred continuously at 250 rpm at room temperature (or specified controlled temp). The test coupon was held static in the stirred solution until the treatment time had elapsed.

When a surface treatment solution was used, the test coupon was immediately removed from the 125 mL PFA bottle after the coupon was immersed in the surface treatment solution for a predetermined treatment time. The coupon was then rinsed by immersing the coupon in DI water and dried by blowing the coupon with a filtered nitrogen gas using a hand held nitrogen gas blower. The coupon was then treated by an etching solution.

After a preset etching time in the etching solution had elapsed, the test coupon was immediately removed from the 125 mL PFA bottle and rinsed by immersing the coupon in a 300 mL volume of ultra-high purity deionized (DI) water for 15 seconds with mild agitation, followed by immersing the coupon in 300 mL of DI water for 15 seconds with mild agitation and a final rinse in 300 mL of DI water for 15 seconds with mild agitation. After the final IPA rinse step, the test coupon was subjected to a filtered nitrogen gas blow off step using a hand held nitrogen gas blower which forcefully removed all traces of DI water to produce a final dry sample for test measurements.

### Example 1

Surface treatment composition 1 (STC-1) was prepared according to General Procedure 1 and contained 3 wt % hexamethyldisilazane and 97 wt % propylene carbonate

Etching compositions 1-3 (EC-1 to EC-3) were prepared according to General Procedure 1 and their formulations are summarized in Table 1.

TABLE 1

| Composition [wt %] | EC-1 | EC-2 | EC-3 |
|---|---|---|---|
| HF | 0.105% | 0.15% | 0.2% |
| H₂O₂ | 7.047% | 7.047% | 8.5% |
| Glacial acetic acid | 47.35% | 47.35% | 69.24% |
| Sulfuric acid | 0.653% | 0.653% | 0.9% |
| Acetic anhydride | 27.5% | 27.5% | None |
| Takesurf A-47Q | 0.01% | 0.01% | 0.01% |
| APDA | 0.01% | 0.01% | 0.01% |
| PBA | 0.05% | 0.05% | None |
| Water | 17.275% | 17.23% | 21.14% |
| Total | 100% | 100% | 100% |
| pH | <1 | <1 | <1 |

APDA = N-(3-aminopropyl)-diethanolamine
PBA = Phenylbroronic acid

Etching composition 1 (EC-1) was evaluated for its etch rates in disclosure processes 1-3 (in which a wafer was pretreated with STC-1 for 30 seconds, 1 minute, or 2 minutes before etching) and in a comparative process 1 (in which no pretreatment before etching was performed). In both the disclosure and comparative processes, EC-1 was used to etch blanket wafers having a SiGe film containing 25 at % Ge (SiGe25-1), blanket wafers have a SiO₂ film, and blanket wafers having a poly-Si film according to General Procedures 2 and 3 for 2 minutes. The surface treatment by STC-1 was performed for 0.5 minute, 1 minute, or 2 minutes at 25° C. and the etching by EC-1 was performed for 2 minutes at 25° C. The evaluation results are summarized in Table 2.

TABLE 2

| | Comparative | Disclosure | Disclosure | Disclosure |
|---|---|---|---|---|
| | Process 1 | Process 1 | Process 2 | Process 3 |
| Surface treatment time | 0 | 0.5 | 1 | 2 |
| (min) | | | | |
| Etching time (min) | 2 | 2 | 2 | 2 |
| SiGe25 ER (Å/min) | 53.1 | 58.37 | 62.49 | 61.11 |
| SiO₂ ER (Å/min) | 3.43 | 0.99 | 0.39 | 0.97 |
| Si ER (Å/min) | 2.06 | 0.98 | 0.83 | 0.68 |
| SiGe25/SiO₂ ER ratio | 15.48 | 58.96 | 158.2 | 63.32 |
| SiGe25/Si ER ratio | 25.74 | 59.26 | 75.75 | 89.86 |

ER = Etch rate

As shown in Table 2, disclosure processes 1-3 (which included a surface treatment step before etching) all exhibited significantly improved SiGe25/SiO₂ and SiGe25/Si etch selectivity compared to comparative process 1 (which did not include a surface treatment step before etching). In other words, the disclosure processes could effectively remove the SiGe film while minimizing the removal of exposed SiO₂ and Si on a semiconductor substrate during an etching process.

Etching compositions 1 and 3 (EC-1 and EC-3) were evaluated for their etch rates in disclosure processes 4-6 and in comparative process 1-3. Disclosure process 4 was performed in the same way as disclosure process 3 described above except that the etching was performed for an extended period of time (i.e., 10 minutes). Disclosure process 5 was performed the same way as disclosure process 3 described above except that EC-1 was replaced by EC-3 (which included a higher amount of HF). Disclosure process 6 was performed the same way as disclosure process 3 described above except that STC-1 was replaced by a surface treatment composition containing 100 wt % hexamethyldisilazane.

TABLE 3

| | Disclosure | Disclosure | Disclosure | Comparative |
|---|---|---|---|---|
| | Process 4 | Process 5 | Process 6 | Process 1 |
| Surface | 2 | 2 | 2 | 0 |
| treatment | | | | |
| time (min) | | | | |
| Etching | 10 | 2 | 2 | 2 |
| time (min) | | | | |
| SiGe25 ER | 62 | 259.3 | 63.76 | 53.1 |
| (Å/min) | | | | |
| SiO₂ ER | 0.13 | 2.22 | 0.66 | 3.43 |
| (Å/min) | | | | |
| Si ER | 2.63 | 8.01 | 1.56 | 2.06 |
| (Å/min) | | | | |
| SiGe25/SiO₂ | 459.22 | 116.54 | 95.87 | 15.48 |
| ER ratio | | | | |
| SiGe25/Si | 23.62 | 32.35 | 40.87 | 25.74 |
| ER ratio | | | | |

As shown in Table 3, disclosure processes 4-6 (which included a surface treatment step before etching) exhibited significantly improved SiGe25/SiO₂ etch selectivity compared to comparative process 1 (which did not include a surface treatment step before etching).

Etching composition 3 (EC-3) was evaluated for its etch rates in disclosure processes 7 and comparative process 2 by etching etch blanket wafers having a SiGe film containing 25 at % Ge (SiGe25-2), blanket wafers having a SiGe film containing 28 at % Ge (SiGe28), blanket wafers having a SiGe film containing 31.5 at % Ge (SiGe31.5), blanket wafers have a SiO₂ film, and blanket wafers having a poly-Si film according to General Procedures 2 and 3. Disclosure process 7 was performed by treating a test coupon with STC-1 in a surface treatment step before etching. Comparative process 2 was performed in the same way as disclosure process 7 except that the surface treatment step by STC-1 was omitted. The evaluation results are summarized in Table 4.

TABLE 4

| | Disclosure Process | Comparative |
|---|---|---|
| | 7 | Process 2 |
| Surface treatment time (min) | 2 | 0 |
| Etching time (min) | 2 | 2 |
| SiGe25-2 ER (Å/min) | 64.99 | 69.32 |
| SiGe28 ER (Å/min) | 94.02 | 112.89 |
| SiGe31.5 ER (Å/min) | 147.19 | 139.31 |
| SiO₂ ER (Å/min) | 0.92 | 39.32 |
| Poly-Si ER (Å/min) | 7.35 | 11.83 |
| SiGe25/SiO₂ ER ratio | 70.64 | 1.65 |
| SiGe25/Si ER ratio | 8.84 | 5.49 |

As shown in Table 4, disclosure process 7 (which included a surface treatment step by using STC-1 before etching) exhibited significantly improved SiGe25/SiO₂ etch selectivity compared to comparative process 2 (which did not include a surface treatment step by using STC-1).

While the invention has been described in detail with reference to certain embodiments thereof, it will be understood that modifications and variations are within the spirit and scope of that which is described and claimed.

What is claimed is:

1. A method for removing silicon germanium (SiGe), comprising:
contacting a semiconductor substrate comprising a SiGe layer on a surface with a surface treatment composition to form a treated surface; and
contacting the treated surface with an etching composition to remove at least a portion of SiGe from the SiGe layer.

2. The method of claim 1, wherein the substrate further comprises a silicon or silicon oxide layer on the surface and the method does not substantially remove the silicon or silicon oxide layer.

3. The method of claim 1, wherein the surface treatment composition comprises at least one Si-containing compound and optionally at least one aprotic solvent.

4. The method of claim 3, wherein the at least one Si-containing compound comprises a disilazane or a disiloxane.

5. The method of claim 3, wherein the at least one Si-containing compound comprises hexamethyldisilazane, heptamethyldisilazane, N-methyl hexamethyldisilazane, 1,3-diphenyltetramethyldisilazane, 1,1,3,3-tetraphenyl-1,3-dimethyldisilazane, 1,1,1-triethyl-3,3-dimethyldisiloxane, 1,1,3,3-tetra-n-octyldimethyldisiloxane, bis(nonafluorohexyl)tetramethyldisiloxane, 1,3-bis(trifluoropropyl)tetramethyldisiloxane, 1,3-di-n-butyltetramethyldisiloxane, 1,3-di-n-octyltetramethyldisiloxane, 1,3-diethyltetramethyldisiloxane, 1,3-diphenyltetramethyldisiloxane, hexa-n-butyldisiloxane, hexaethyldisiloxane, hexavinyldisiloxane, 1,1,1,3,3-pentamethyl-3-acetoxydisiloxane, 1-allyl-1,1,3,3-tetramethyldisiloxane, 1,3-bis(3-aminopropyl)tetramethyldisiloxane, 1,3-bis(heptadecafluoro-1,1,2,2-tetrahydrodecyl)tetramethyldisiloxane, 1,3-divinyltetraphenyldisiloxane, 1,3-divinyltetramethyldisiloxane, 1,3-diallyltetrakis(trimethylsiloxy)disiloxane, 1,3-diallyltetramethyldisiloxane, 1,3-diphenyltetrakis(dimethylsiloxy)disiloxane, (3-chloropropyl)pentamethyldisiloxane, 1,3-divinyltetrakis(trimethylsiloxy)disiloxane, 1,1,3,3-tetraisopropyldisiloxane, 1,1,3,3-tetravinyldimethyldisiloxane, 1,1,3,3-tetracyclopentyldichlorodisiloxane, vinylpentamethyldisiloxane, 1,3-bis(3-chloroisobutyl)tetramethyldisiloxane, hexaphenyldisiloxane, 1,3-bis[(bicyclo[2.2.1]hept-2-enyl)ethyl]tetramethyldisiloxane, 1,1,1-triethyl-3,3,3-trimethyldisiloxane, 1,3-bis(3-methacryloxypropyl)tetramethyldisiloxane, 1,3-bis(chloromethyl)tetramethyldisiloxane, 1,1,3,3-tetramethyl-1,3-diethoxydisiloxane, 1,1,3,3-tetraphenyldimethyldisiloxane, methacryloxypentamethyldisiloxane, pentamethyldisiloxane, 1,3-bis(3-chloropropyl)tetramethyldisiloxane, 1,3-bis(4-hydroxybutyl)tetramethyldisiloxane, 1,3-bis(triethoxysilylethyl)tetramethyldisiloxane, 3-aminopropylpentamethyldisiloxane, 1,3-bis(2-aminoethylaminomethyl)tetramethyldisiloxane, 1,3-bis(3-carboxypropyl)tetramethyldisiloxane, 1,3-dichloro-1,3-diphenyl-1,3-dimethyldisiloxane, 1,3-diethynyltetramethyldisiloxane, n-butyl-1,1,3,3-tetramethyldisiloxane, 1,3-dichlorotetraphenyldisiloxane, 1,3-dichlorotetramethyldisiloxane, 1,3-di-t-butyldisiloxane, 1,3-dimethyltetramethoxydisiloxane, 1,3-divinyltetraethoxydisiloxane, 1,1,3,3-tetraethoxy-1,3-dimethyldisiloxane, vinyl-1,1,3,3-tetramethyldisiloxane, platinum-[1,3-bis(cyclohexyl)imidazol-2-ylidene hexachlorodisiloxane, 1,1,3,3-tetraisopropyl-1-chlorodisiloxane, 1,1,1-trimethyl-3,3,3-triphenyldisiloxane, or 1,3-bis(trimethylsiloxy)-1,3-dimethyldisiloxane.

6. The method of claim 3, wherein the at least one Si-containing compound is from about 0.5 wt % to about 10 wt % of the surface treatment composition.

7. The method of claim 3, wherein the surface treatment composition further comprises the at least one aprotic solvent and the at least one aprotic solvent is selected from the group consisting of carbonate solvents, lactones, ketones, aromatic hydrocarbons, siloxanes, glycol dialkyl ethers, glycol alkyl ether acetates, esters, ureas, lactams, dimethyl sulfoxide, and N-methyl pyrrolidone.

8. The method of claim 7, wherein the at least one aprotic solvent comprises a carbonate solvent.

9. The method of claim 8, wherein the carbonate solvent is propylene carbonate.

10. The method of claim 3, wherein the at least one aprotic solvent is from about 90 wt % to about 99.9 wt % of the surface treatment composition.

11. The method of claim 1, wherein the etching composition comprises:
at least one fluorine-containing acid, the at least one fluorine-containing acid comprising hydrofluoric acid or hexafluorosilicic acid;
at least one oxidizing agent;
at least one catalyst comprising sulfuric acid, a sulfonic acid, or a phosphonic acid;
at least one organic acid or an anhydride thereof, the at least one organic acid comprising formic acid, acetic acid, propionic acid, or butyric acid;
at least one polymerized naphthalene sulfonic acid or a salt thereof; and
at least one amine, the at least one amine comprising an amine of formula (1): N—R₁R₂R₃, wherein R₁ is C₁-C₈ alkyl optionally substituted by OH or NH₂, R₂ is H or C₁-C₈ alkyl optionally substituted by OH, and R₃ is C₁-C₈ alkyl optionally substituted by OH.

12. The method of claim 11, wherein the at least one fluorine-containing acid is in an amount of from about 0.01 wt % to about 2 wt % of the etching composition.

13. The method of claim 11, wherein the at least one oxidizing agent comprises hydrogen peroxide or peracetic acid.

14. The method of claim 11, wherein the at least one oxidizing agent is in an amount of from about 5 wt % to about 20 wt % of the etching composition.

15. The method of claim 11, wherein the at least one catalyst comprises sulfuric acid, methanesulfonic acid, phosphonic acid, or phenylphosphonic acid.

16. The method of claim 11, wherein the at least one catalyst is in an amount of from about 0.1 wt % to about 5 wt % of the etching composition.

17. The method of claim 11, wherein the at least one organic acid or an anhydride thereof comprises acetic acid or acetic anhydride.

18. The method of claim 11, wherein the total amount of the at least one organic acid or an anhydride thereof is from about 30 wt % to about 90 wt % of the etching composition.

19. The method of claim 11, wherein the at least one polymerized naphthalene sulfonic acid comprises a sulfonic acid having a structure of 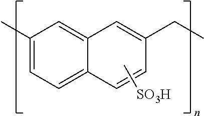
in which n is 3 to 6.

20. The method of claim 11, wherein the at least one polymerized naphthalene sulfonic acid or a salt thereof is in an amount of from about 0.001 wt % to about 0.15 wt % of the etching composition.

21. The method of claim 11, wherein the amine of formula (I) is diisopropylamine, N-butyldiethanolamine, N-(3-aminopropyl)-diethanolamine, N-octylglucamine, N-ethylglucamine, N-methylglucamine, or 1-[bis(2-hydroxyethyl)amino]-2-propanol.

22. The method of claim 11, wherein the at least one amine is in an amount of from about 0.001 wt % to about 0.15 wt % of the etching composition.

23. The method of claim 11, further comprising at least one boronic acid.

24. The method of claim 23, wherein the boronic acid has a formula of R—B(OH)₂, in which R is C₁-C₁₀ alkyl, aryl, or heteroaryl, the aryl or heteroaryl being optionally substituted by one to six C₁-C₁₀ alkyl.

25. The method of claim 24, wherein the boronic acid is phenyl boronic acid.

26. The method of claim 23, wherein the at least one boronic acid is in an amount of from about 0.01 wt % to about 0.5 wt % of the etching composition.

27. The method of claim 11, further comprising water.

28. The method of claim 27, wherein the water is in an amount of from about 10 wt % to about 50 wt % of the etching composition.

29. The method of claim 11, wherein the etching composition has a pH of from about 0 to about 3.

30. The method of claim 1, wherein the method does not include a step of oxidizing the surface before the surface is contacted with the surface treatment composition.

31. The method of claim 1, wherein the method has a SiGe/Si etch selectivity or a SiGe/SiOx etch selectivity of from about 30 to about 200.

32. An article formed by the method of claim 1, wherein the article is a semiconductor device.

33. The article of claim 32, wherein the semiconductor device is an integrated circuit.
